(19) United States
(12) Patent Application Publication
(10) Pub. No.: US 2025/0364876 A1
(43) Pub. Date: Nov. 27, 2025

(54) ELECTRIC MACHINE FOR A MOTOR VEHICLE, ROTOR FOR AN ELECTRIC MACHINE AND MOTOR VEHICLE

(71) Applicant: AUDI AG, Ingolstadt (DE)

(72) Inventor: Daniel RUPPERT, Lenting (DE)

(21) Appl. No.: 19/214,807

(22) Filed: May 21, 2025

(30) Foreign Application Priority Data
May 22, 2024 (DE) 102024114278.2

(51) Int. Cl. H02K 11/042; H01F 38/18; H02K 1/26; H02K 1/32; H02K 7/00; H02K 11/33; H02K 19/02

(52) U.S. Cl. CPC H02K 11/042; H01F 38/18; H02K 1/26; H02K 1/32; H02K 7/006; H02K 11/33; H02K 19/02; H02K 2211/03

(57) ABSTRACT

An electric machine for a motor vehicle is disclosed, and may include a stator, a rotor rotatably mounted with respect to the stator and having rotor windings for generating a rotor magnetic field, and an active rectifier provided on the rotor. The active rectifier may electrically connect a voltage source present on the rotor to the rotor windings, and may be configured to convert an alternating voltage provided by the voltage source into a direct voltage. The direct voltage may be configured to be utilized during generation of the rotor magnetic field by the rotor windings. The active rectifier may be arranged on or in a cooling section of the rotor. The cooling section may form a heat sink through which a cooling fluid can flow.

### BACKGROUND

### Technical Field

The present disclosure relates to an electric machine, in particular an externally excited synchronous machine, for a motor vehicle, comprising a stator and a rotor rotatably mounted with respect to the stator and having rotor windings for generating a rotor magnetic field.

### Description of the Related Art

Electric machines are often used as traction motors in motor vehicles, which can be purely electric vehicles or hybrid vehicles. Electric machines comprise a stator and a rotor rotatably mounted with respect to the stator, wherein windings made of a conductor wire and, if appropriate, permanent magnets are provided on the part of the stator and on the part of the rotor, wherein electromagnetic interactions between the magnetic fields generated by the windings and, if appropriate, the permanent magnets result in the generation of a drive or braking torque. Particularly in electric machines used as traction motors, the power transmissions typically occurring are so high that active cooling of the components involved is necessary. Examples in connection with cooling systems in electric machines are known from the prior art, for example from the published patent applications DE102010032827A1 and U.S. Patent Application Publication No. 2015/0280525A1.

In electric machines, such as externally excited synchronous machines, the use of permanent magnets on the part of the rotor is often dispensed with. Instead, windings are provided on the part of the rotor to generate the required rotor magnetic field resulting in additional degrees of freedom in the context of control and design of the electric machine. However, as a result, the rotor windings provided on the part of the rotor require the rotor windings to be electrically energized. For this purpose, power is transmitted from a stationary part of the electric machine, which can also be understood or referred to as the stator, to the rotor, for example via slip ring contacts or contactlessly via inductive transmission means. When inductive transmission means are used in this regard, an electrical alternating voltage is generated on the part of the rotor, which must be converted into a direct voltage required to generate the rotor magnetic field by means of the rotor windings. Such a system, in which a passive rectifier provided on the rotor side in this regard is also cooled, is known from DE102021213736A1.

### BRIEF SUMMARY

The present disclosure provides an improved concept in connection with cooling taking place on the part of a rotor of an electric machine.

According to the present disclosure, an electric machine of the type mentioned at the outset includes an active rectifier provided on the part of the rotor. The rectifier electrically connects a voltage source present on the part of the rotor to the rotor windings and by way of which an alternating voltage provided by the voltage source is convertible into a direct voltage which can be utilized in the course of generating the rotor magnetic field by the rotor windings. The rectifier is arranged on or in a cooling section of the rotor which forms a heat sink and through which a cooling fluid can flow.

The present disclosure provides an active rectifier on the part of the rotor, which, especially in comparison with a passive rectifier, generates more heat and must be cooled. Due to the heat generation, a rectifier is often the component of the electric machine that limits the maximum power that can be generated by the electric machine. To achieve an improvement in this regard, the active rectifier is arranged on the heat sink, so that a thermal coupling between the heat sink and the rectifier enables or increases the dissipation of thermal energy from the rectifier. For this purpose, the rectifier may be in direct contact, preferably in touching contact with the heat sink, apart from a thermally conductive medium provided for fastening the rectifier. A cavity provided for guiding the cooling fluid, in particular a cooling channel, may be positioned directly below the rectifier in this case. The cooling fluid may be a cooling liquid, such as water or oil.

The rotor is rotatably mounted with respect to the stator, which typically has stator windings for generating a stator magnetic field. For this purpose, a rotor shaft can be mounted via appropriate bearings, such as ball or roller bearings. The rotor and stator may be arranged within a housing of the electric machine, with the stator preferably being arranged stationary with respect to the housing.

The rotor windings and/or the stator windings may have at least one electrically conductive wire wound, for example, around rotor or stator teeth. The windings function as a field coil, which may generate a magnetic field, i.e., the rotor magnetic field or the stator magnetic field, when electrically energized.

An active rectifier is understood to mean, in particular, an electrical component comprising a plurality of controllable semiconductor components, such as transistors. Thus, the active rectifier, or at least some of the semiconductor components of the active rectifier, may be controlled by control signals, wherein the control signals may be directed to control the operation of the rectifier, for example, to implement a rectifier and, if appropriate, an inverter. In contrast, passive rectifiers typically only have semiconductor diodes, so that an alternating voltage applied to an input of the rectifier is always converted, independently of control signals, into a direct voltage at a rectifier's output.

Below, definitions of relevant spatial directions for the electric machine according to the present disclosure are introduced. The rotor is rotatably mounted about an axis of rotation, which extends along a longitudinal direction of the electric machine. The radial direction extends perpendicular to the longitudinal direction. A circumferential direction, in turn, is perpendicular to the radial direction. This means that a point rotating about the axis of rotation moves along the circumferential direction. The longitudinal, radial, and circumferential directions with respect to the rotor correspond to the longitudinal, radial, and circumferential directions with respect to the electric machine.

The electric machine according to the present disclosure may comprise an inductive rotary transformer, comprising at least one rotor-side field coil present on the part of the rotor and forming the voltage source, and at least one stator-side field coil present on the part of the stator, wherein electrical energy may be transmitted inductively from the stator-side field coil to the rotor-side field coil. The inductive rotary transformer may enable contact-free and therefore low-wear or wear-free transmission of power from the stator or the stationary section to the rotor. The rotor-side field coil and the stator-side field coil may move past each other during the rotation of the rotor, wherein magnetic fields generated on the part of the stator-side field coil cause a voltage to occur on the part of the rotor-side field coil by way of electromagnetic induction. The rotor-side field coil may thus function as the voltage source, in which the generated voltage is present as an alternating voltage. By way of the rectifier, this alternating voltage may be converted into the direct voltage required to operate the stator windings. Preferably, a plurality of field coils may be provided which are arranged concentrically about an axis of rotation of the rotor and thus along the circumferential direction.

In some embodiments, in the context of de-excitation, in particular rapid de-excitation, of the rotor by way of the rectifier, a direct voltage present on the part of the rotor windings may be convertible into an alternating voltage, wherein the electrical energy extracted from the rotor windings in this case may be transmitted inductively from the rotor-side field coil to the stator-side field coil. While during normal operation of the electric machine, power is typically transmitted from the stator to the rotor, situations are conceivable in which power transmission in the opposite direction is necessary or expedient. Corresponding situations may include, for example, failure or accident scenarios in which a reduction of the rotor magnetic field is required. For this purpose, a flow of current present in the rotor windings must be reduced. For this purpose, the rectifier may be put into a state by way of appropriate control commands in which the direct voltage present on the part of the rotor windings is converted into an alternating voltage, which in turn is applied to the rotor-side field coil. Accordingly, power may be dissipated to the stator-side field coil. In the context of this embodiment, a bidirectional transmission of power or energy is possible by way of the rotary transformer and the rectifier.

According to the present disclosure, the electric machine may have an inductive communication rotary transformer comprising at least one rotor-side communication coil present on the part of the rotor and at least one stator-side communication coil present on the part of the stator, wherein electrical control signals that may be utilized to control the rectifier, may be transmitted inductively from the stator-side communication coil to the rotor-side communication coil. The aspects explained in connection with the inductive rotary transformer apply in principle equally and analogously to the communication rotary transformer. It is thus conceivable for the electric machine or the associated motor vehicle, in particular, to have a control device connected to the stator-side communication coil, which may be configured to generate the control signals directed toward the operation of the rectifier and present on the part of the stator and to output them to the stator-side communication coil for transmission to the rotor.

With respect to the heat sink, the cooling section may have at least one cooling channel through which the cooling fluid can flow. A cooling channel is understood to mean an elongated hollow space or a corresponding cavity, wherein the cooling fluid flows through the cooling channel along its longitudinal direction.

In some embodiments, in the cooling channel or in at least one of the cooling channels, at least one channel wall delimiting the cooling channel may be provided with a baffle deflecting, in particular swirling, the fluid flowing along the channel wall. Generally speaking, the baffle may be any geometric shape of the surface of the channel wall that deviates from a smooth or flat structure. The baffle may have bulges arranged on the inside of the cooling channel and projecting or protruding from the channel wall. The baffle may be provided, and may only be provided, in a section of the cooling channel that is located directly below the rectifier. The baffle may have the effect of converting any laminar flow of the cooling fluid present in the cooling channel into a turbulent flow, so that heat is transmitted to the cooling fluid more effectively.

The baffle may comprise at least one cooling fin and/or at least one cooling rib. A cooling fin or cooling rib is understood to mean, in particular, a web-like, elongated structure whose longitudinal direction extends along the channel wall. The longitudinal direction may be arranged perpendicularly or obliquely with respect to the flow direction of the cooling fluid, thereby correspondingly increasing the deflection effect on the cooling fluid. The baffle may comprise a plurality of cooling fins or cooling ribs arranged one after the other with respect to the flow direction.

The electric machine according to the present disclosure may have a rotor shaft connected to the rotor or forming part of the rotor, which may have at least one shaft channel which penetrates the rotor shaft at least in sections and extends along a longitudinal direction and through which the cooling fluid can flow, wherein the cooling fluid may be supplied to the cooling section via the shaft channel or one of the shaft channels and/or discharged from the cooling section via the shaft channel or one of the shaft channels. The shaft channel or one of the shaft channels may be arranged concentrically or eccentrically with respect to the axis of rotation. If a plurality of shaft channels are provided, the plurality of shaft channels may extend through various longitudinal sections of the rotor shaft. If the plurality of shaft channels extend at least partially through the same longitudinal section of the rotor shaft, the plurality of shaft channels may be arranged offset from one another along the radial direction and/or the circumferential direction. An introduction lance may be provided for introducing the cooling fluid into the shaft channel. For introducing the cooling fluid into the shaft channel and/or for discharging the cooling fluid from the shaft channel, the rotor shaft may have at least one transverse bore communicating with the respective shaft channel and extending along the radial direction.

The cooling section may be a disk. The disk may preferably extend concentrically about the axis of rotation. The disk may have a circular shape when viewed along the longitudinal direction. The disk may be a balancing disk of the rotor. The balancing disk may be used to prevent any imbalance of the rotor, for example, by removing material from the balancing disk, thus ensuring the smoothest possible running of the rotor. The disk may be arranged on an end face of the rotor, i.e., at one of the two axial ends of the rotor.

In some embodiments, a hollow interior of the disk, which may form the at least one cooling channel, may be shaped such that the cooling fluid flows outward in the disk along a radial direction and then flows inward along the radial direction. The hollow interior or the respective cooling channel may have a U-shape, wherein the two longitudinal beams of the U-shape may extend radially outward and may be connected via the transverse beam of this U-shape, which may be arranged radially on the outside of the disk and extends along the circumferential direction.

The rectifier may comprise at least one circuit board, in particular one having electrically conductive conductor tracks, and semiconductor components arranged thereon and utilizable in the context of rectifying the alternating voltage, wherein the circuit board may be fastened to the cooling section. The circuit board is understood to mean a printed circuit board on which the semiconductor components are arranged. The circuit board may be made of a plastic. The semiconductor components may be fastened to the circuit board by way of soldering and/or press-fit connections. The circuit board may have a flat, such as planar, extent which may extend parallel to an outer surface of the cooling section, which supports the circuit board, in order to achieve the most effective thermal connection possible.

A thermally conductive medium may be arranged between the circuit board and the cooling section. A thermally conductive medium is understood to mean a material with a sufficiently high thermal conductivity coefficient to ensure the most effective heat transfer from the rectifier to the cooling section. The thermal conductivity coefficient may have a value of at least 10 W/(m K). The thermally conductive medium may be a thermally conductive adhesive and, in addition to ensuring the most effective heat transfer possible, also serves as a fastener by which the rectifier is fastened to the cooling section.

Additionally or alternatively, the circuit board may have a metal core. Due to the high thermal conductivity coefficient typically found in metals, heat transfer through the circuit board, which occurs in the context of the heat transfer from the semiconductor components to the cooling fluid, is even more effective. This is advantageous, for example, when a support structure of the circuit board is made of a plastic, apart from the metal core and any conductor tracks present. The metal core may be made of aluminum and/or copper. The metal core may be covered by a layer of plastic, particularly with respect to the direction toward the semiconductor components. The same generally applies to the direction toward the cooling section, wherein the metal core may also be exposed in this regard, so that direct contact can exist between the metal core and the cooling section, apart from any thermally conductive medium.

In some embodiments, the electric machine may be connectable to a drive train of a motor vehicle, wherein, in relation to the state connected to the drive train, a traction torque may be generated by way of the electric machine and transmitted to the wheels of the motor vehicle via the drive train. For example, an open end of a rotor shaft of the rotor extending along the axis of rotation may be provided, which may protrude from the housing of the electric machine. This end and a component of the drive train may each have a connecting device, such as a connecting flange, by way of which a mechanical connection, in particular a rotationally fixed one, may be established between the shaft and the drive train. The drive train is generally understood to mean any and all components via which a mechanical coupling can be established between the electric machine and the wheels. The drive train may therefore comprise drive shafts and/or transmissions, in particular manual and/or differential gears and/or clutches.

The present disclosure further relates to a rotor for an electric machine for a motor vehicle, wherein the rotor may be rotatably mounted with respect to a stator of the electric machine, wherein the rotor may have rotor windings for generating a rotor magnetic field. According to the present disclosure, such a rotor may have a voltage source and an active rectifier electrically connecting the voltage source to the rotor windings, by way of which an alternating voltage provided by the voltage source convertible into a direct voltage which may be utilized in the course of generating the rotor magnetic field by the rotor windings, wherein the rectifier may be arranged on or in a cooling section of the rotor, which may form a heat sink and through which a cooling fluid can flow. All advantages, features, and aspects explained in connection with the electric machine according to the present disclosure are equally applicable to the rotor according to the present disclosure, and vice versa.

Furthermore, the present disclosure relates to a motor vehicle. The motor vehicle according to the present disclosure may have a traction motor configured as an electric machine according to the above description. The electric machine may be connected to a drive train of the motor vehicle, wherein a traction torque may be generated by way of the electric machine and transmitted to wheels of the motor vehicle via the drive train. All advantages, features, and aspects explained in connection with the electric machine according to the present disclosure and the rotor according to the present disclosure are equally transferable to the motor vehicle according to the disclosure, and vice versa.

The motor vehicle according to the present disclosure may comprise a cooling system by way of which the cooling fluid may be guided, wherein the cooling section forming the heat sink may be integrated into the cooling system. Thus, the cooling system may form a cooling circuit in which the cooling fluid may be conveyed by way of a conveying device. In this embodiment, the cooling fluid may circulate from the conveying device to the cooling section and back again and is thus recirculated. The conveying device may be a cooling fluid pump. A cooling device for cooling the cooling fluid, such as a heat exchanger, may be integrated into the cooling system.

The motor vehicle according to the present disclosure may comprise an electrical energy storage device in which energy required during the traction of the motor vehicle may be stored. This energy may be present in the form of electrical energy and may be converted into kinetic energy by the electric machine. Conversely, the electric machine may be operated in a recuperation mode, in which kinetic energy of the motor vehicle is converted into electrical energy, which may be stored in particular in the electrical energy storage device. A direct voltage may typically be provided by way of the electrical energy storage device, which may be a lithium-ion battery. However, an alternating voltage may be required for the operation of the electric machine, so that a power electronics unit may be provided on the part of the electric machine, by way of which the direct voltage provided by the electrical energy storage device is convertible into an alternating voltage. The aforementioned or a further control device may be configured to generate control signals directed toward the operation of the power electronics unit and to output the control signals to the power electronics unit.

### BRIEF DESCRIPTION OF THE SEVERAL VIEWS OF THE DRAWINGS

FIG. 1 shows a schematic diagram of a side view of a motor vehicle according to an example embodiment of the present disclosure.

FIG. 2 shows a schematic diagram of the electric machine of the motor vehicle of FIG. 1.

FIG. 3 shows a longitudinal section view of a portion of the electric machine of the motor vehicle of FIG. 1.

FIG. 4 shows a sectional view of a portion of a rectifier of the rotor of the electric machine of FIG. 3.

### DETAILED DESCRIPTION

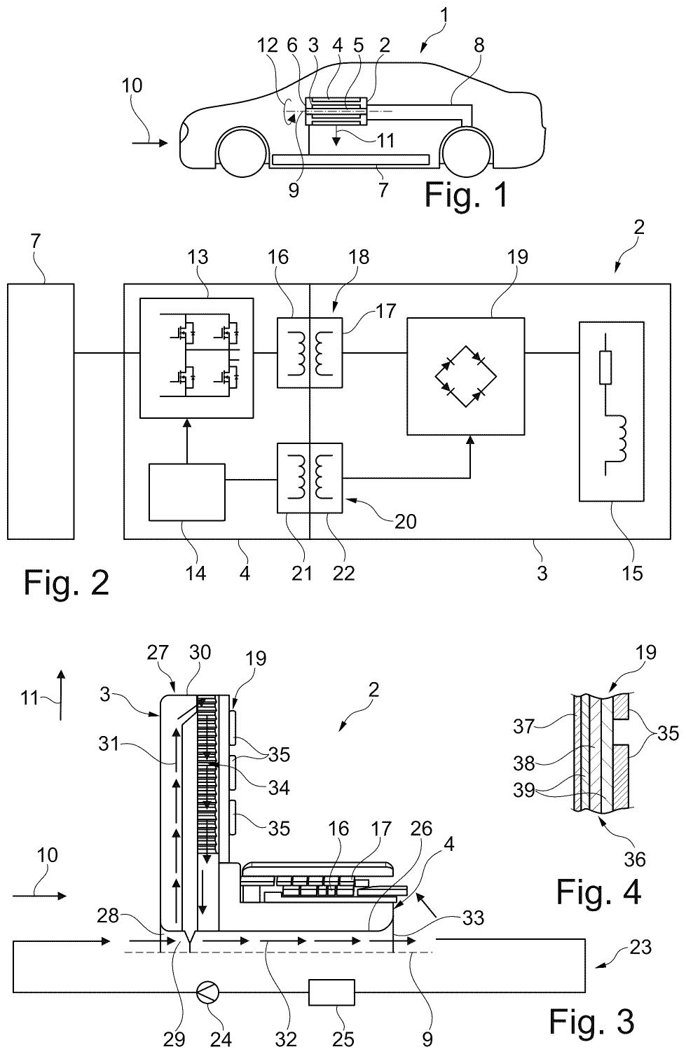

FIG. 1 shows a motor vehicle 1 according to the present disclosure according to an example embodiment, comprising an electric machine 2 according to the present disclosure according to an example embodiment. Electric machine 2 comprises a rotor 3 according to the present disclosure according to an example embodiment, and a stator 4. Electric machine 2 may be an internal rotor configured as an externally excited synchronous machine. Rotor 3 may therefore be arranged in a region of electric machine 2 that is radially further inward than a region in which stator 4 is arranged. A rotor shaft 5 of rotor 3 may be rotatably mounted on a housing 6 of electric machine 2, for example, by way of a ball or roller bearing.

Electric machine 2 may be configured to be operated in a drive mode in which electrical energy stored in an electrical energy storage device 7 of motor vehicle 1 is converted into kinetic energy of motor vehicle 1. A generated drive torque, which may be utilized to propel motor vehicle 1, may be transmitted from electric machine 2 to a drive train 8 of motor vehicle 1. The drive torque may only be transmitted to the rear wheels, but may additionally or alternatively be transmitted to the front wheels. Electric machine 2 may additionally be operated in a recuperation mode in which kinetic energy of motor vehicle 1 is converted into electrical energy by way of electric machine 2, and such electrical energy may be utilized, for example, to charge electrical energy storage device 7.

Below, definitions with respect to relevant spatial directions are introduced with regard to electric machine 2. Rotor shaft 5 is rotatably mounted about an axis of rotation 9, which extends along a longitudinal direction 10 of electric machine 2. A radial direction 11 extends perpendicular to longitudinal direction 10. A circumferential direction 12 is perpendicular to radial direction 11. This means that a point rotating about the axis of rotation 9 moves along circumferential direction 12.

Details with respect to electric machine 2 are explained below with reference to FIGS. 2 and 3. FIG. 2 shows a schematic view of electric machine 2, which particularly illustrates the distribution of the components of electric machine 2 across rotor 3 and stator 4. A power electronics unit 13 may be provided on a part of stator 4 or the stationary section, by way of which a direct voltage provided by electrical energy store 7 is convertible into an alternating voltage. For this purpose, a control device 14 may be provided, which may be configured to generate control signals that control the operation of power electronics unit 13 and to output the control signals to the power electronics unit 13. The alternating voltage generated by power electronics unit 13 may be used to electrically energize the stator windings of stator 4, which is not shown in detail in the figures, and rotor windings 15 of rotor 3, of which only one is indicated schematically in FIG. 2. Stator windings and rotor windings 15, each of which comprise a conductor wire, generate magnetic fields due to the electrical energization by way of the rotor magnetic field and a stator magnetic field interacting with each other in the course of generating the drive or recuperation torque.

Details regarding the transmission of electrical energy or power from energy storage device 7 to stator windings 15 are explained below. First, the direct voltage provided by energy storage device 7 may be converted into an alternating voltage by way of power electronics unit 13. This alternating voltage may be transmitted to a stator-side field coil 16 present on the part of stator 4, via which an inductive energy transfer may be transmitted to a rotor-side field coil 17 present on the part of rotor 3. Field coils 16, 17 may thus form an inductive rotary transformer 18, via which a contactless energy transfer from stator 4 or stationary section of electric machine 2 to its rotor 3 may be enabled.

Rotor-side field coil 17 may implement a voltage source present on the part of rotor 3, by way of which an alternating electrical voltage may be generated. This alternating voltage may be supplied to an input of an active rectifier 19 of rotor 3, which may convert this alternating voltage into a direct voltage present at an output. Rectifier 19 thus may connect rotor-side field coil 17 to rotor windings 15, so that the voltage provided via rotor-side field coil 17 and converted into a direct voltage by rectifier 19 may be supplied to rotor windings 15 for generating the rotor magnetic field.

Active rectifier 19 may comprise semiconductor components 35, wherein the rectification of the alternating voltage provided by rotor-side field coil 17 may occur as a function of control signals. Thus, although semiconductor diodes are only symbolically indicated in FIG. 2 in this regard, active rectifier 19 may comprise controllable semiconductor components 35, namely, transistors. In the present case, active rectifier 19 may not only be used to convert the alternating voltage present on the input side, or on the part of rotor-side field coil 17, into a direct voltage present on the output side, or on the part of rotor windings 15, but also vice versa, provided that corresponding control signals for active rectifier 19 are present.

This reverse case, in which active rectifier 19 is used to convert a direct voltage present on the part of rotor windings 15 into an alternating voltage present on rotor-side field coil 17, is particularly relevant in the context of de-excitation of rotor 3. Such de-excitation, or rapid de-excitation, may be necessary, for example, in a failure or accident scenario and may cause the rotor magnetic field to be reduced. In the context of the de-excitation, control signals may be generated and output to active rectifier 19. The control signals may cause the direct voltage present on rotor windings 15 to be converted into an alternating voltage, which in turn may cause an inductive energy transfer from rotor-side field coil 17 to stator-side field coil 16.

In addition to generating the control signals provided for power electronics unit 13, control device 14 may further be configured to generate the previously mentioned control signals directed toward the operation of active rectifier 19 and to output the control signals to said active rectifier 19 via an inductive communication rotary transformer 20. Communication rotary transformer 20 may comprise a stator-side communication coil 21 present on the part of stator 4 and a rotor-side communication coil 22 present on the part of rotor 3, wherein the control signals of control device 14 intended for the operation of active rectifier 19 may be transmitted inductively from stator-side communication coil 21 to rotor-side communication coil 22. The functional principle of communication rotary transformer 20 may be fundamentally the same as that of rotary transformer 18.

Details regarding a cooling system 23 of motor vehicle 1 are explained below with reference to FIG. 3. Cooling system 23 guides a cooling fluid and forms a cooling circuit. Accordingly, cooling system 23 may comprise a conveying device 24, such as a feed pump, by way of which the circulation of the cooling fluid is driven. Furthermore, cooling system 23 may comprise a cooling device 25 for cooling the cooling fluid, namely a heat exchanger.

In addition to schematically indicated cooling system 23, FIG. 3 shows the upper half of a longitudinal section through a portion of electric machine 2. In this case, only a part of rotor 3 and stator 4 are shown, wherein in particular the upper half of a rotor shaft 26 extending along axis of rotation 9 is indicated.

The cooling effect achieved by way of cooling system 23 cools rectifier 19 present on the part of rotor 3, which is necessary because rectifier 19, as an actively controlled component, is subject to increased heat generation compared to a passive rectifier, for example. For this purpose, rectifier 19 may be arranged on a cooling section 27 of rotor 3 that forms a heat sink and which may be integrated into cooling system 23 and through which the cooling fluid flows. The specific flow path of the cooling fluid is indicated by arrows in FIG. 3.

The cooling fluid thus may pass from conveying means 24 to an inlet opening 28 arranged on the end face of rotor 3 or rotor shaft 26, via which the cooling fluid may be introduced via an introduction lance, which is not shown in detail, into a supply shaft channel 29 which may penetrate rotor shaft 26 in sections and extends along longitudinal direction 10. The cooling fluid may then enter cooling section 27, which, in the present case, is a disk 30 arranged on the end face of rotor 3 and functions as a balancing disk.

Supply shaft channel 29 may open into a hollow interior of disk 30, which may form a cooling channel 31 of cooling section 27 or of disk 30. With regard to the longitudinal sectional representation of FIG. 3, cooling channel 31 has an inverted U-shape, so that the cooling channel 31 initially leads radially outward from supply shaft channel 29 into a radially outer region of disk 30, and then radially inward, where cooling channel 31 finally opens into a discharge shaft channel 32. Said discharge shaft channel 32 may also pass through the rotor shaft 26 in sections and may extend along longitudinal direction 10. With regard to cooling section 27, supply shaft channel 29 may extend on one side and discharge shaft channel 32 may extend on the other side of rotor shaft 26. The cooling fluid may leave electric machine 2 or rotor 3 via an outlet opening 33 which may be, with regard to inlet opening 28, located on the opposite end face, from where the cooling fluid reaches cooling device 25 and conveying device 24.

Specifically, with respect to cooling rectifier 19, a portion of cooling channel 31 extending through cooling section 27 may be arranged directly below rectifier 19, such as, in the present case, the radially inward-leading section of the corresponding U-shape. The thickness of the material of cooling section 27 remaining between cooling channel 31 and rectifier 19 may be as small as possible to enable the most effective heat transfer from rectifier 19 to the cooling fluid, and may only be a few millimeters.

In the region of cooling channel 31 located directly below rectifier 19, a baffle 34 may be provided on a channel wall delimiting cooling channel 31, by way of said baffle, the cooling fluid flowing through cooling channel 31 may be deflected and swirled. The baffle may enable a more efficient transfer of heat from rectifier 19 to the cooling fluid. The baffle may comprise a plurality of elongated, web-like structures arranged one after the other perpendicular to the flow direction, which may also be referred to as cooling fins or cooling ribs.

Details with respect to the structure of rectifier 19 are explained below. For this purpose, reference is made to FIG. 4, which shows a sectional view through a portion of rectifier 19, wherein the sectional plane is arranged perpendicularly to a flat and planar printed circuit board or circuit board 36. Cooling section 27 supporting rectifier 19 is not shown in FIG. 4. Thus, rectifier 19 may comprise circuit board 36, on which semiconductor components 35 may be arranged. Circuit board 36 may be fastened to cooling section 27 or disk 30 by way of a layer of a heat-conducting medium 37, which may be a thermal adhesive. This layer may be arranged between circuit board 36 and cooling section 27.

Furthermore, circuit board 36 may comprise a metal core 38 made of aluminum and/or copper, which may be arranged between two layers 39 made of a plastic. Layer 39 facing cooling section 27 may also be omitted, so that metal core 38 is exposed and may be in direct contact with heat-conducting medium 37 or cooling section 27. Heat-conducting medium 37 and metal core 38 may improve or increase the effectiveness of the heat transfer from rectifier 19 or semiconductor components 35 to the cooling fluid.

German patent application no. 102024114278.2, filed May 22, 2024, to which this application claims priority, is hereby incorporated by reference in its entirety.

Aspects of the various embodiments described above can be combined to provide further embodiments. In general, in the following claims, the terms used should not be construed to limit the claims to the specific embodiments disclosed in the specification and the claims, but should be construed to include all possible embodiments along with the full scope of equivalents to which such claims are entitled.

1. An electric machine for a motor vehicle, comprising:
a stator;
a rotor rotatably mounted with respect to the stator and having rotor windings for generating a rotor magnetic field; and
an active rectifier provided on the rotor, the active rectifier electrically connecting a voltage source present on the rotor to the rotor windings and configured to convert an alternating voltage provided by the voltage source into a direct voltage, the direct voltage configured to be utilized during generating of the rotor magnetic field by the rotor windings,
wherein the active rectifier is arranged on or in a cooling section of the rotor, the cooling section forming a heat sink through which a cooling fluid can flow.

2. The electric machine according to claim 1, further comprising an inductive rotary transformer, the inductive rotary transformer comprising:
at least one rotor-side field coil present on the rotor and forming the voltage source; and
at least one stator-side field coil present on the stator,
wherein the inductive rotary transformer is configured such that electrical energy can be transmitted inductively from the stator-side field coil to the rotor-side field coil.

3. The electric machine according to claim 2, wherein the active rectifier is configured such that during de-excitation of the rotor by way of the active rectifier a direct voltage present on the rotor windings is converted into an alternating voltage, wherein the electrical energy extracted from the rotor windings is transmitted inductively from the rotor-side field coil to the stator-side field coil.

4. The electric machine according to claim 1, further comprising an inductive communication rotary transformer, the communication rotary transformer comprising at least one rotor-side communication coil present on the rotor and at least one stator-side communication coil present on the stator, wherein electrical control signals configured to control operation of the active rectifier are transmitted inductively from the stator-side communication coil to the rotor-side communication coil.

5. The electric machine according to claim 1, wherein the cooling section has at least one cooling channel configured such that the cooling fluid can flow through the at least one cooling channel.

6. The electric machine according to claim 5, wherein in one or more of the at least one of the cooling channel at least one channel wall delimiting the respective cooling channel is provided with a baffle configured to deflect the cooling fluid flowing along the channel wall.

7. The electric machine according to claim 6, wherein the baffle has at least one cooling fin and/or at least one cooling rib.

8. The electric machine according to claim 6, wherein the baffle is configured to swirl the cooling fluid flowing along the channel wall.

9. The electric machine according to claim 1, further comprising a rotor shaft connected to the rotor or forming part of the rotor, the rotor shaft having at least one shaft channel penetrating the rotor shaft at least in sections and extending along a longitudinal direction, the at least one shaft channel configured such that the cooling fluid can flow through the at least one shaft channel, wherein the cooling fluid is supplied to the cooling section via one or more of the at least one shaft channel and/or discharged from the cooling section via one or more of the at least one shaft channel.

10. The electric machine according to claim 1, wherein the cooling section is a disk.

11. The electric machine according to claim 10, wherein a hollow interior of the disk forms the at least one cooling channel and is configured such that the cooling fluid flows outward in the disk along a radial direction and then flows inward along the radial direction.

12. The electric machine according to claim 10, wherein the disk is arranged on an end face of the rotor.

13. The electric machine according to claim 1, wherein the active rectifier comprises at least one circuit board and semiconductor components arranged on the at least one circuit board, the semiconductor components configured to be used to rectify the alternating voltage, wherein the circuit board is fastened to the cooling section.

14. The electric machine according to claim 13, wherein a heat-conducting medium is arranged between the circuit board and the cooling section, and/or the circuit board has a metal core.

15. The electric machine according to claim 14, wherein the heat-conducting medium is a thermally conductive adhesive.

16. The electric machine according to claim 14, wherein the metal core comprises aluminum and/or copper.

17. The electric machine according to claim 1, wherein the electric machine is an externally excited synchronous machine.

18. A rotor for an electric machine for a motor vehicle, the rotor comprising:
rotor windings for generating a rotor magnetic field;
a voltage source; and
an active rectifier electrically connecting the voltage source to the rotor windings, the active rectifier configured to convert an alternating voltage provided by the voltage source into a direct voltage, the direct voltage configured to be utilized during generating of the rotor magnetic field by the rotor windings, wherein the active rectifier is arranged on or in a cooling section of the rotor, the cooling section of the rotor forming a heat sink through which a cooling fluid can flow,
wherein the rotor is configured to be rotatably mounted with respect to a stator of the electric machine.

19. A motor vehicle comprising:
a traction motor configured as an electric machine, the electric machine comprising:
a stator;
a rotor rotatably mounted with respect to the stator and having rotor windings for generating a rotor magnetic field; and
an active rectifier provided on the rotor, the active rectifier electrically connecting a voltage source present on the rotor to the rotor windings and configured to convert an alternating voltage provided by the voltage source into a direct voltage configured to generate the rotor magnetic field by the rotor windings,
wherein the active rectifier is arranged on or in a cooling section of the rotor, the cooling section forming a heat sink through which a cooling fluid can flow,
wherein the electric machine is connected to a drive train of the motor vehicle,
wherein the electric machine is configured to generate a traction torque, and
wherein the drive train is configured to transmit the traction torque to wheels of the motor vehicle.

20. The motor vehicle according to claim 19, further comprising a cooling system forming a cooling circuit configured to guide the cooling fluid, wherein the cooling section forming the heat sink is integrated into the cooling system.
